(19) United States
(12) Patent Application Publication
(10) Pub. No.: US 2026/0182222 A1
(43) Pub. Date: Jun. 25, 2026

(54) DISPLAY DEVICE

(71) Applicant: LG Display Co., Ltd., Seoul (KR)

(72) Inventor: JongSuk SHIN, Paju-si (KR)

(73) Assignee: LG Display Co., Ltd., Seoul (KR)

(21) Appl. No.: 19/387,261

(22) Filed: Nov. 12, 2025

(30) Foreign Application Priority Data
Dec. 20, 2024 (KR) 10-2024-0192309

(51) Int. Cl. H10K 59/80

(52) U.S. Cl. CPC H10K 59/878; H10K 59/80518; H10K 59/8792

(57) ABSTRACT

A display device is provided in which a light transmittance of a variable area within a light control layer changes according to whether a voltage is applied between a first electrode and a reflective electrode. The variable area may include an electrochromic material that transitions between transparent and opaque states in response to the applied voltage, thereby adjusting brightness and reflectivity. In another embodiment, a display device includes a light control layer having a first solvent area and a second solvent area, wherein the position or area of the first solvent area changes depending on the voltage applied to the reflective electrode. This configuration allows dynamic modulation of light transmission and reflection, enabling improved visibility, reduced reflectance, and enhanced operational stability under varying ambient light conditions.

### CROSS-REFERENCE TO RELATED APPLICATIONS

This application claims the benefit of the Republic of Korea Patent Application No. 10-2024-0192309 filed on December 20, 2024, each of which is hereby incorporated by reference in its entirety.

### BACKGROUND

### TECHNICAL FIELD

The present disclosure relates to a display device.

### DESCRIPTION OF THE RELATED ART

As an information society develops, a demand for a display device for displaying an image is increasing in various forms. Accordingly, various display devices such as a liquid crystal display (LCD) device, a plasma display panel (PDP), and an organic light emitting display (OLED) device have recently been used.

Among the display devices, the organic light emitting display device is a self-luminous type, has better viewing angle and contrast ratio than the liquid crystal display (LCD) device, and has an advantage of being lightweight and thin because a separate backlight is not required, and power consumption is advantageous. In addition, the organic light emitting display device has an advantage of being driven with a low direct current (DC) voltage, having a fast response speed, and especially low manufacturing cost.

### BRIEF SUMMARY

In order to improve the efficiency of a light emitting device, display devices that eliminate a polarizing plate while employing a color filter have been proposed. However, removal of the polarizing plate can lead to increased reflectance caused by external light. To mitigate such reflectance, the aperture ratio of the display device may be reduced, which undesirably increases the current density of the light emitting device and consequently shortens its operational lifetime. The present disclosure has been made in view of the foregoing issues, and an aspect of the present disclosure is to provide a display device which can be selectively driven to be suitable for a low-luminance and high-luminance environment.

In particular, the present disclosure relates to a display device that includes a light control layer positioned between a reflective electrode and a light emitting device, which adjusts light transmittance in response to an applied voltage. The light control layer includes a variable area made of an electrochromic material whose transparency changes according to the voltage difference between the first electrode and the reflective electrode. By selectively transmitting or blocking light, the device adapts its brightness and reflectivity to surrounding lighting conditions, improving visibility in both indoor and outdoor environments while reducing lateral leakage current and extending the operational lifetime of the light emitting elements.

In one embodiment, the light control layer includes three functional regions: a transparent area, a variable area, and a blocking area arranged to optimize light emission and contrast. The variable area surrounds the transparent area and changes its optical state under electrical control, while the blocking area absorbs light in non emission regions to minimize optical interference and reflection. This configuration enables efficient use of the emission aperture and enhances image clarity without the need for external polarizers or filters.

In another embodiment, the light control layer includes an electrowetting based dual solvent system in which a first solvent with light blocking properties and a second solvent with reflective or transparent properties change positions according to applied voltage. A through hole in the reflective electrode allows movement of the solvents, enabling smooth control of reflected and emitted light. These structural features allow the display device to maintain high luminance in indoor environments and reduced reflectance in bright outdoor settings, providing improved optical efficiency and stable operation compared to conventional OLED displays.

In accordance with an aspect of the present disclosure, the above and other technical effects can be accomplished by the provision of a display device comprising a substrate having a plurality of sub-pixels, each of the plurality of sub-pixels including an emission area and a non-emission area surrounding the emission area, wherein each of the plurality of sub-pixels include a reflective electrode disposed on the substrate in the emission area, a light control layer disposed on the reflective electrode and including a variable area, and a light emitting device disposed on the light control layer and including a first electrode, wherein the variable area is disposed in the emission area adjacent to the non-emission area, and wherein a light transmittance of the variable area is changed, according to whether voltages are applied to the first electrode and the reflective electrode.

In addition to, in accordance with an aspect of the present disclosure, the above and other technical effects can be accomplished by the provision of a display device comprising a substrate having a plurality of sub-pixels, each of the plurality of sub-pixels including an emission area and a non-emission area surrounding the emission area, wherein each of the plurality of sub-pixels include a reflective electrode disposed on the substrate in the emission area, a light control layer disposed on the reflective electrode and including a first solvent area, and a light emitting device disposed on the light control layer and including a first electrode, wherein the first solvent area is disposed in the emission area and includes a material having a light blocking function, and wherein an area in which the first solvent area is disposed changes according to whether a voltage is applied to the reflective electrode.

It is to be understood that both the foregoing general description and the following detailed description are exemplary and explanatory and are intended to provide further explanation of the inventive concepts as claimed

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description explain the principle of the disclosure. In the drawings:

FIG. 1 is a plan view of a display device according to an embodiment of the present disclosure.

FIG. 2 is a plan view of a plurality of pixels according to an embodiment of the present disclosure.

FIG. 3 is a plan view of one pixel according to a first embodiment of the present disclosure.

FIG. 4 is a cross-sectional view of one sub-pixel according to a first embodiment of the present disclosure.

FIG. 5 is a cross-sectional view of one sub-pixel according to a first embodiment of the present disclosure.

FIG. 6 is a cross-sectional view of one sub-pixel according to a first embodiment of the present disclosure.

FIG. 7 is a plan view of one pixel according to a second embodiment of the present disclosure.

FIG. 8 is a cross-sectional view of one sub-pixel according to a second embodiment of the present disclosure.

FIG. 9 is a cross-sectional view of one sub-pixel according to a second embodiment of the present disclosure.

FIG. 10 is a cross-sectional view of one sub-pixel according to a second embodiment of the present disclosure.

Throughout the drawings and the detailed description, unless otherwise described, the same drawing reference numerals should be understood to refer to the same elements, features, and structures.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure, and implementation methods thereof, will be clarified through the following examples described with reference to the accompanying drawings. The present disclosure may, however, be embodied in different forms and should not be construed as limited to the examples set forth herein. Rather, these examples are provided so that the specification of the present disclosure will be thorough, complete, and fully convey the scope of the present disclosure to those skilled in the art.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Unless stated otherwise, like reference numerals refer to like elements throughout the specification. In the following description, when the detailed description of the relevant known function or configuration is determined to unnecessarily obscure an important point of the present disclosure, the detailed description will be omitted. In a case where ‘comprise’, ‘have’, and ‘include’ described in the present disclosure are used, another portion may be added unless ‘only~’ is used. The terms of a singular form may include plural forms unless referred to the contrary.

In interpreting the components, it is interpreted as including an error range even if there is no separate explicit description of an error range.

In describing a position relationship, for example, when the position relationship is described as ‘upon~’, ‘above~’, ‘below~’ and ‘next to~’, one or more portions may be disposed between two other portions unless ‘just’ or ‘direct’ is used. The terms, such as “below,” “lower,” “above,” “upper”, and the like, may be used herein to describe a relationship between elements as illustrated in the drawings. It will be understood that the terms are spatially relative and based on the orientation depicted in the drawings.

A description of a time relationship may include a case in which the temporal precedence relationship is described as “after”, “following”, or “before”, etc., and is not continuous unless “right away” or “directly”, is used.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

Although the first, second, and the like are used to describe various components, these components are not limited by these terms. These terms are used only to distinguish one component from another. Therefore, a first component mentioned below may be a second component within a technical idea of a present disclosure.

The phrase “A filled in B” does not imply that A is exclusively contained within B to the exclusion of other materials. Instead, it is intended to encompass a broad range of conditions, including but not limited to “partially filled in,” “substantially filled in,” “completely filled in,” and “exclusively filled in.” Similarly, the phrase “B filled with A” does not suggest that B is exclusively filled with A, excluding other materials. Rather, it covers various degrees of filling, such as “partially filled with,” “substantially filled with,” “completely filled with,” and “exclusively filled with.”

It will be understood that, although the terms “first,” “second,” “A,” “B,” “(a),” and “(b)”, etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of each of the various examples of the present disclosure may be partially or entirely coupled or combined with each other, technically various interworking and driving are possible, and each of the examples may be independently implemented with respect to each other or may be implemented together in a related relationship.

Hereinafter, one embodiment of the present disclosure will be described in detail with reference to the accompanying drawings.

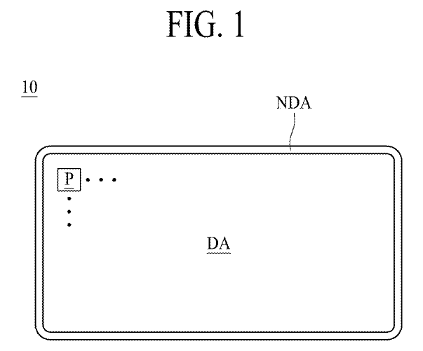

FIG. 1 is a plan view of a display device according to an embodiment of the present disclosure.

Referring to FIG. 1, the display device 10 according to an embodiment of the present disclosure may include a display area DA and a non-display area NDA surrounding the display area DA. The display area DA is an area in which an image may be displayed, and the non-display area NDA is an area in which an image is not displayed.

The display area DA may include a plurality of pixels P. The plurality of pixels P may be arranged in a matrix form consisting of a plurality of rows and columns. In addition, the non-display area NDA may include a plurality of wirings, pads, driving circuits, etc., for driving the plurality of pixels P.

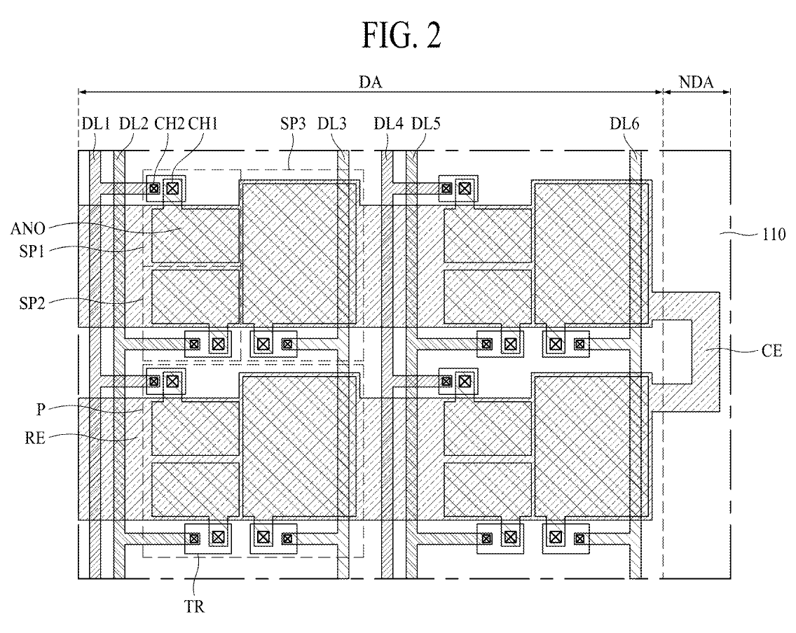

FIG. 2 is a plan view of a plurality of pixels P according to an embodiment of the present disclosure.

As described above, the display area DA may include the plurality of pixels P. The plurality of pixels P may be disposed on a first substrate 110 and may be disposed in a matrix form including a plurality of rows and columns.

Referring to FIG. 2, each of the plurality of pixels P may include a plurality of sub-pixels. The plurality of sub-pixels may include a first sub-pixel SP1, a second sub-pixel SP2, and a third sub-pixel SP3. The first sub-pixel SP1, the second sub-pixel SP2, and the third sub-pixel SP3 may emit different light from each other. For example, the first sub-pixel SP1 may emit red light, the second sub-pixel SP2 may emit green light, and the third sub-pixel SP3 may emit blue light, but the present disclosure is not limited thereto. In addition, FIG. 2 shows that one pixel P includes three sub-pixels SP1, SP2 and SP3, but is not limited thereto. For example, one pixel P may include more than three sub-pixels

A thin film transistor TR and a first electrode ANO may be disposed in each of the first sub-pixel SP1, the second sub-pixel SP2, and the third sub-pixel SP3. The first electrode ANO may function as an anode in a light emitting device.

In each of the first sub-pixel SP1, the second sub-pixel SP2, and the third sub-pixel SP3, an area of the first electrode ANO may extend to an upper portion of the thin film transistor TR. The first electrode ANO may be electrically connected to the thin film transistor TR through a first contact hole CH1. The first electrode ANO may receive a voltage through the thin film transistor TR.

A data line may be disposed on the first substrate 110. The data line may be disposed in an area between adjacent pixels P or below the pixel P. FIG. 2 illustrates that first and second data lines DL1 and DL2 are disposed between adjacent pixels P, and a third data line DL3 is disposed below the pixel P, but is not limited thereto.

An area of the data line may extend to an upper portion of the thin film transistor TR. The data line may be electrically connected to the thin film transistor TR through a second contact hole CH2. The thin film transistor TR may receive a voltage through the data line.

A first data line DL1 may be electrically connected to the thin film transistor TR of the plurality of first sub-pixels SP1 disposed in the same column, a second data line DL2 may be electrically connected to the thin film transistor TR of the plurality of second sub-pixels SP2 disposed in the same column, and a third data line DL3 may be electrically connected to the thin film transistor TR of the plurality of third sub-pixels SP3 disposed in the same column. A fourth data line DL4 may be electrically connected to the thin film transistor TR of the plurality of first sub-pixels SP1 disposed in the same column, and a fifth data line DL5 may be electrically connected to the thin film transistor TR of the plurality of second sub-pixels SP2 disposed in the same column, and a sixth data line DL6 may be electrically connected to the thin film transistor TR of the plurality of third sub-pixels SP3 disposed in the same column.

A reflective electrode RE may be disposed under the first electrode ANO. The reflective electrode RE may reflect incident light. The reflective electrode RE may include a metal material such as aluminum (Al), silver (Ag), copper (Cu), molybdenum (Mo), titanium (Ti), tungsten (W), or chromium (Cr), or an alloy thereof.

Between the plurality of sub-pixels disposed in one pixel P, the reflective electrode RE may be continuously formed. In detail, the reflective electrodes RE of each of the first sub-pixel SP1, the second sub-pixel SP2, and the third sub-pixel SP3 disposed in one pixel P may be continuously formed. In addition, the reflective electrodes RE may be continuously formed in a plurality of pixels P disposed in the same row. In addition, the reflective electrodes RE disposed in different rows may be electrically connected through a connection electrode CE. The connection electrode CE may be formed by extending a portion of the reflective electrode RE to the non-display area NDA. Accordingly, the reflective electrodes RE may have the same potential in the plurality of pixels P. In addition, the reflective electrodes RE may have the same potential in the plurality of sub-pixels.

FIG. 2 shows that the reflective electrode RE does not overlap the thin film transistor TR, but is not limited thereto. Also, FIG. 2 shows that the reflective electrode RE overlaps the data line , but is not limited thereto.

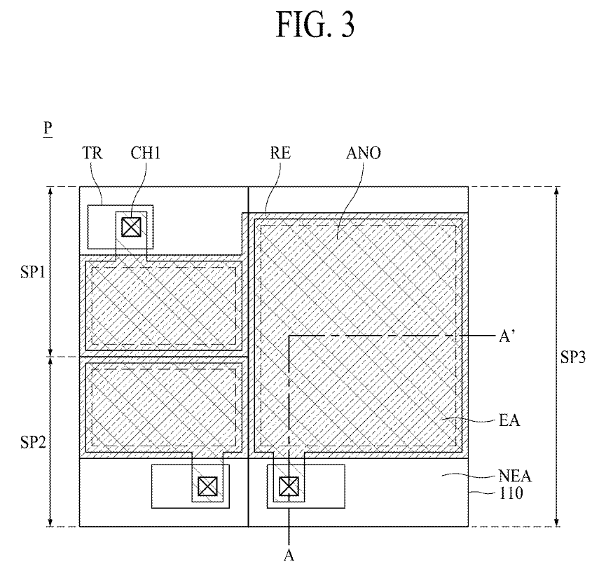

FIG. 3 is a plan view of one pixel P according to a first embodiment of the present disclosure. In FIG. 3, a view of the data line is omitted.

As described above, one pixel P may include the first sub-pixel SP1, the second sub-pixel SP2, and the third sub-pixel SP3. FIG. 3 illustrates that an area of the third sub-pixel SP3 is larger than an area of each of the first sub-pixel SP1 and the second sub-pixel SP2, but is not limited thereto.

Each of the first sub-pixel SP1, the second sub-pixel SP2, and the third sub-pixel SP3 may include an emission area EA and a non-emission area NEA surrounding the emission area EA. The emission area EA is an area capable of emitting light, and the non-emission area NEA is an area that does not emit light.

As described above, the thin film transistor TR and the first electrode ANO may be disposed in each of the first sub-pixel SP1, the second sub-pixel SP2, and the third sub-pixel SP3.

In each of the first sub-pixel SP1, the second sub-pixel SP2, and the third sub-pixel SP3, the first electrode ANO may be disposed in the entire emission area EA, and may also be disposed in a partial area of the non-emission area NEA. In addition, the first electrodes ANO of each of the first sub-pixel SP1, the second sub-pixel SP2, and the third sub-pixel SP3 may be spaced apart from each other.

In each of the first sub-pixel SP1, the second sub-pixel SP2, and the third sub-pixel SP3, the thin film transistor TR may be disposed in the non-emission area NEA. In FIG. 3, the thin film transistor TR of the first sub-pixel SP1 is disposed at an upper side of the first sub-pixel SP1, the thin film transistor TR of the second sub-pixel SP2 is disposed at a lower side of the second sub-pixel SP2, and the thin film transistor TR of the third sub-pixel SP3 is disposed at a lower side of the third sub-pixel SP3, but is not limited thereto.

A reflective electrode RE may be disposed under the first electrode ANO. In each of the first sub-pixel SP1, the second sub-pixel SP2, and the third sub-pixel SP3, the reflective electrode RE is disposed in the entire emission area EA, and may also be disposed in a partial area of the non- emission area NEA. In addition, the reflective electrode RE of each of the first sub-pixel SP1, the second sub-pixel SP2, and the third sub-pixel SP3 may be continuously formed.

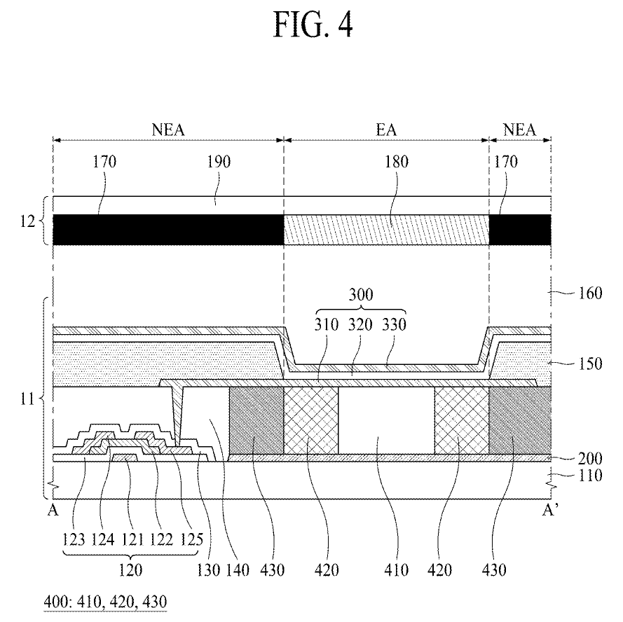

FIG. 4 is a cross-sectional view of one sub-pixel according to a first embodiment of the present disclosure. In detail, it is a cross-sectional view of one sub-pixel taken along line A-A′ illustrated in FIG. 3. FIG. 4 is a cross-sectional view of the third sub-pixel SP2, but the present disclosure is not limited thereto. For example, it may be a cross-sectional view of any one of the first sub-pixel SP1 and the second sub-pixel SP2 illustrated in FIG. 3.

Referring to FIG. 4, one sub-pixel according to an embodiment of the present disclosure may include a circuit unit 11 and a color filter unit 12. The circuit unit 11 may include a first substrate 110, a thin film transistor 120, a passivation layer 130, a planarization layer 140, a bank 150, a light emitting device 300, and a light control layer 400. The color filter unit 12 may include a black matrix 170, a color filter 180, and a second substrate 190. The circuit unit 11 and the color filter unit 12 may be bonded by an encapsulation layer 160.

The first substrate 110 may be formed of glass or plastic, but is not limited thereto. The display device according to an embodiment of the present disclosure may be configured in a top emission type in which emitted light is emitted upward. Therefore, as a material of the first substrate 110, not only a transparent material but also an opaque material may be used.

The thin film transistor 120 may be disposed on the first substrate 110. The thin film transistor 120 may include a gate electrode 121, a semiconductor layer 122, a gate insulating layer 123, a source electrode 124, and a drain electrode 125.

The gate electrode 121 of the thin film transistor 120 may be disposed on the first substrate 110. In addition, the semiconductor layer 122 may be disposed on the gate electrode 121. The semiconductor layer 122 may include a poly-silicon semiconductor or an oxide semiconductor. In addition, when the semiconductor layer 122 includes an oxide semiconductor, at least one oxide of indium-gallium-zinc-oxide (IGZO), indium-gallium-tin-oxide (IGO), and indium-gallium-oxide (IGO) may be included.

To insulate the gate electrode 121 from the semiconductor layer 122, the gate insulating layer 123 may be disposed between the gate electrode 121 and the semiconductor layer 122. The gate insulating layer 123 may be composed of a single layer of silicon nitride (SiNx) or silicon oxide (SiOx), or multiple layers thereof. In addition, FIG. 4 illustrates a bottom gate structure in which the semiconductor layer 122 is disposed on the gate electrode 121, but is not limited thereto. For example, a top gate structure in which the gate electrode 121 is disposed on the semiconductor layer 122 may be used.

The source electrode 124 and the drain electrode 125 may be disposed on the semiconductor layer 122 while facing each other. In addition, the passivation layer 130 may be disposed on the source electrode 124 and the drain electrode 125. A contact hole exposing a portion

of the drain electrode 125 may be formed in the passivation layer 130. In addition, the passivation layer 130 may be formed of an inorganic insulating material such as silicon oxide (SiOx), silicon nitride (SiNx), silicon oxynitride (SiOxNy), or the like.

The reflective electrode 200 may be disposed on the first substrate 110. The reflective electrode 200 may be disposed on the same layer as the gate electrode 121, but is not limited thereto. In addition, the reflective electrode 200 may be formed of the same material as the gate electrode 121, but is not limited thereto. For example, the reflective electrode 200 may be disposed on the same layer as the source electrode 124 or the drain electrode 125.

The planarization layer 140 may be disposed on the thin film transistor 120 and the reflective electrode 200. The planarization layer 140 may compensate for a step difference caused by the thin film transistor 120 to planarize an upper area of the thin film transistor 120. In addition, the planarization layer 140 may be formed of an organic insulating material such as an acrylic resin, an epoxy resin, a phenolic resin, a polyamide resin, or a polyimide resin.

The bank 150 may be disposed on the planarization layer 140 and in the non-emission area NEA. The bank 150 may expose a partial area of the planarization layer 140.

The bank 150 may include an organic insulating material such as an acrylic resin, an epoxy resin, a phenolic resin, a polyamide resin, a polyimide resin, etc. Alternatively, the bank 150 may include an inorganic insulating material such as silicon oxide (SiOx), silicon nitride (SiNx), silicon oxynitride (SiOxNy), etc. In this case, the bank 150 may further include a material absorbing light. For example, the bank 150 may be a black bank.

The light emitting device 300 may be disposed on the planarization layer 140. The light emitting device 300 may include a first electrode 310, a light emitting layer 320, and a second electrode 330.

The first electrode 310 is disposed on the planarization layer 140 and may function as an anode of the light emitting device. The first electrode 310 may be electrically connected to the thin film transistor 120 through a contact hole disposed in the passivation layer 130 and the planarization layer 140. FIG. 4 illustrates that the first electrode 310 is electrically connected to the drain electrode 125, but is not limited thereto. For example, the first electrode 310 may be electrically connected to the source electrode 124.

The first electrode 310 may be disposed on the planarization layer 140 exposed by the bank 150. In addition, an end of the first electrode 310 may be covered by the bank 150. The first electrode 310 may be disposed in the emission area EA.

The first electrode 310 may include a transparent conductive material such as indium tin oxide (ITO) or indium zinc oxide (IZO). Further, although illustrated as a single layer, the first electrode 310 may be formed as multiple layers.

The light emitting layer 320 may be disposed on the first electrode 310. The light emitting layer 320 may cover the entire upper surface of the first electrode 310 not covered by the bank 150. In addition, the light emitting layer 320 may be disposed on the bank 150. That is, the light emitting layer 320 may be disposed in the emission area EA and the non-emission area NEA.

The light emitting layer 320 may include a hole transporting layer, an emission layer, and an electron transporting layer. In this case, when a voltage is applied to the first electrode 310 and the second electrode 330, holes and electrons move to the light emission layer through the hole transport layer and the electron transport layer, respectively, and holes and electrons may combine with each other in the emission layer to emit light.

The second electrode 330 may be disposed on the light emitting layer 320. The second electrode 330 may function as a cathode of the light emitting device. Like the light emitting layer 320, the second electrode 330 may also be disposed on the bank 150. That is, the second electrode 330 may be disposed in the emission area EA and the non-emission area NEA.

Since the display device according to an embodiment of the present disclosure is configured in a top emission type, the second electrode 330 may include a transparent conductive material such as an indium tin oxide (ITO) or an indium zinc oxide (IZO) to transmit light emitted from the light emitting layer 320 upward.

The encapsulation layer 160 may be disposed on the light emitting device 300. The encapsulation layer 160 may compensate for a step difference caused by the light emitting device 300. The encapsulation layer 160 may include an organic insulating material such as an acrylic resin, an epoxy resin, a phenolic resin, a polyamide resin, or a polyimide resin. The encapsulation layer 160 may be disposed in the emission area EA and the non-emission area NEA.

The black matrix 170, the color filter 180, and the second substrate 190 may be disposed on the encapsulation layer 160.

The second substrate 190 may be disposed in the emission area EA and the non-emission area NEA. The second substrate 190 may be formed of glass or plastic, but is not limited thereto. Since the display device according to an embodiment of the present disclosure is configured in a top emission type, a transparent material may be used as a material of the second substrate 190.

The black matrix 170 may be disposed between the second substrate 190 and the encapsulation layer 160. The black matrix 170 may be disposed in the non-emission area NEA. The black matrix 170 may expose a partial area of the second substrate 190. A width of the black matrix 170 may be less than or equal to a width of the bank 150.

The color filter 180 may be disposed between the second substrate 190 and the encapsulation layer 160. A color filter 180 may be disposed on a lower surface of the second substrate 190 exposed by the black matrix 170. That is, a color filter 180 may be disposed in the emission area EA.

The color filter 180 may transmit only light of a specific wavelength band. For example, the color filter 180 may transmit only any one light of red, green, and blue.

Meanwhile, the light control layer 400 may be disposed between the reflective electrode 200 and the light emitting device 300. The light control layer 400 may be disposed in the entire emission area EA and may also be disposed in a partial area of the non-emission area NEA. One side of the light control layer 400 may be in contact with the planarization layer 140. In addition, an upper surface of the light control layer 400 may be in contact with the first electrode 310, and a lower surface of the light control layer 400 may be in contact with the reflective electrode 200.

The light control layer 400 may include a transparent area 410, a variable area 420, and a blocking area 430.

The transparent area 410 may be a central area of the light control layer 400. The transparent area 410 may be disposed in the emission area EA and may not be disposed in the non- emission area NEA. That is, the transparent area 410 may not overlap the bank 150.

The transparent area 410 may be formed of a transparent material. For example, the transparent area 410 may include an organic insulating material such as an acrylic resin, an epoxy resin, a phenolic resin, a polyamide resin, a polyimide resin and the like. Alternatively, the transparent area 410 may include an inorganic insulating material such as silicon oxide (SiOx), silicon nitride (SiNx), silicon oxynitride (SiOxNy), and the like.

The variable area 420 may surround the transparent area 410. One side of the variable area 420 may be in contact with the transparent area 410. The variable area 420 may be disposed in the emission area EA adjacent to the non-emission area NEA, and may not be disposed in the non-emission area NEA. That is, the variable area 420 may not overlap the bank 150.

The variable area 420 may include an electrochromic material. When a voltage is not applied, the electrochromic material may be in a transparent state. That is, when a voltage is not applied, the electrochromic material may transmit light. In addition, when a voltage is applied, the electrochromic material may be discolored in an electric field direction, and the electrochromic material may be in an opaque state by an oxidation-reduction reaction. That is, when a voltage is applied, the electrochromic material may absorb or block light. Accordingly, depending on whether a voltage is applied, the light transmittance of the light control layer 400 may be changed.

Referring to FIG. 4, the reflective electrode 200 may be disposed under the variable area 420 and the transparent area 410. An upper surface of the variable area 420 may be in contact with the first electrode 310, and a lower surface of the variable area 420 may be in contact with the reflective electrode 200. Accordingly, a state of the variable area 420 may be changed according to whether voltages are applied to the first electrode 310 and the reflective electrode 200. Specifically, when a voltage is not applied to the first electrode 310 and the reflective electrode 200, the variable area 420 may be in the transparent state. That is, the variable area 420 may transmit light. In addition, when a voltage is applied to the first electrode 310 and the reflective electrode 200, the variable area 420 may be in the opaque state. That is, the variable area 420 may absorb or block light. Accordingly, the light transmittance of the variable area 420 may be changed according to whether voltages are applied to the first electrode 310 and the reflective electrode 200.

As described above, the first electrode 310 may receive a voltage through the thin film transistor 120. In addition, although not shown in FIG. 4, the reflective electrode 200 may receive a voltage through an additional thin film transistor or an external driving unit. That is, the first electrode 310 and the reflective electrode 200 are not electrically connected to each other, and the first electrode 310 and the reflective electrode 200 may receive different voltages from each other. Accordingly, the first electrode 310 and the reflective electrode 200 may be used as electrodes for driving the variable area 420.

The blocking area 430 may surround the variable area 420. One side of the blocking area 430 may be in contact with the planarization layer 140, and the other side of the blocking area 430 may be in contact with the variable area 420. That is, the variable area 420 may be disposed between the transparent area 410 and the blocking area 430, and the blocking area 430 may be disposed between the planarization layer 140 and the variable area 420. The blocking area 430 may be disposed in the non-emission area NEA and may not be disposed in the emission area EA. That is, the blocking area 430 may overlap the bank 150.

The blocking area 430 may include an organic insulating material such as an acryl resin, an epoxy resin, a phenolic resin, a polyamide resin, a polyimide resin and the like. Alternatively, the blocking area 430 may include an inorganic insulating material such as silicon oxide (SiOx), silicon nitride (SiNx), silicon oxynitride (SiOxNy), and the like. In addition, the blocking area 430 may further include a material that absorbs light. Accordingly, the blocking area 430 may absorb light introduced into the non-emission area NEA.

The transparent area 410, the variable area 420, and the blocking area 430 may have the same thickness. In addition, the transparent area 410, the variable area 420, and the blocking area 430 may be disposed on the same layer. In addition, heights of upper surfaces of the transparent area 410, the variable area 420, and the blocking area 430 may be the same as a height of an upper surface of the planarization layer 140. Accordingly, the first electrode 310 may be stably disposed on the planarization layer 140 and the light control layer 400.

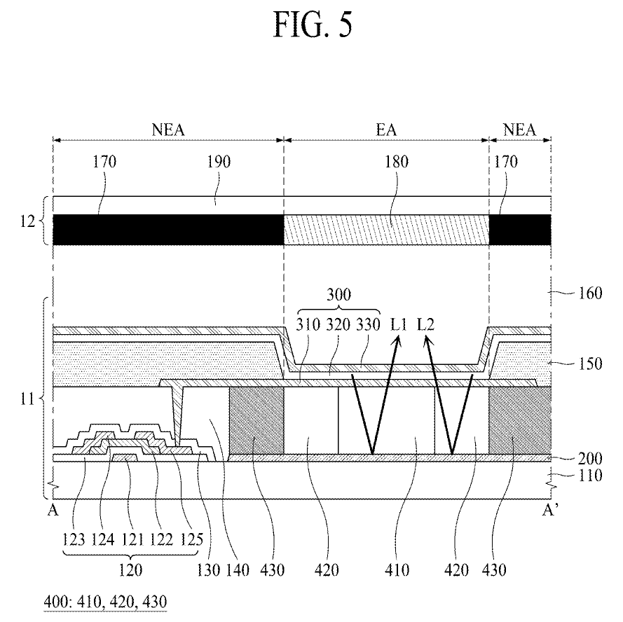

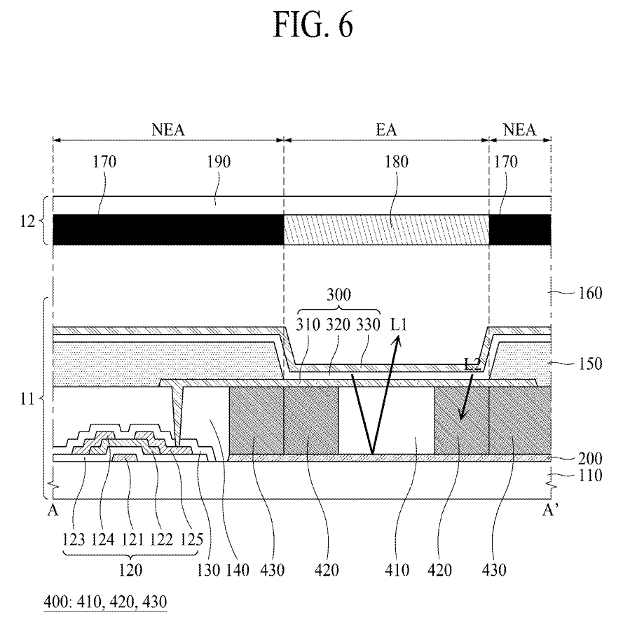

FIGS. 5 and 6 are cross-sectional views of one sub-pixel according to a first embodiment of the present disclosure. In particular, FIGS. 5 and 6 illustrate a state of the variable area 420 in detail.

FIG. 5 illustrates a case in which a voltage is not applied to the first electrode 310 and the reflective electrode 200. Since a voltage is not applied to the first electrode 310 and the reflective electrode 200, the variable area 420 may be in a transparent state.

Meanwhile, some of light generated in the light emitting layer 320 may not be directed to the second substrate 190 but may be directed to the first substrate 110. Referring to FIG. 5, a first light L1 and a second light L2 may be generated in the light emitting layer 320.

The first light L1 may be light directed to the transparent area 410. As described above, since the transparent area 410 is formed of a transparent material, the first light L1 may pass through the transparent area 410 and be directed to the reflective electrode 200. Accordingly, the first light L1 may be reflected by the reflective electrode 200 to be directed to the second substrate 190.

The second light L2 may be light directed to the variable area 420. As described above, since the variable area 420 is in the transparent state, the second light L2 may pass through the variable area 420 and may be directed to the reflective electrode 200. Accordingly, the second light L2 may be reflected by the reflective electrode 200 to be directed to the second substrate 190.

In conclusion, light of the light emitting layer 320 directed to the first substrate 110 may pass through the transparent area 410 or the variable area 420, and may be reflected by the reflective electrode 200 to be directed to the second substrate 190. Accordingly, since an amount of light emitted toward an upper side of the display device increases, an image having high luminance may be displayed. Particularly, in a low luminance environment such as indoors, the user’s visibility may be improved.

In addition, since the variable area 420 is used in the transparent state, the reflective electrode 200 disposed in the entire emission area EA defined by the bank 150 may be used. That is, an aperture ratio of the display device may be used to the maximum. In particular, since the aperture ratio of the display device is used to the maximum while a luminance of the display device is improved, a lifespan of the light emitting device 300 may be improved.

Meanwhile, FIG. 6 illustrates a case in which voltages are applied to the first electrode 310 and the reflective electrode 200. Since voltages are applied to the first electrode 310 and the reflective electrode 200, the variable area 420 may be in the opaque state.

As described above, some of light generated in the light emitting layer 320 may not be directed to the second substrate 190, but may be directed to the first substrate 110. Referring to FIG. 6, a first light L1 and a second light L2 may be generated in the light emitting layer 320.

The first light L1 may be light directed to the transparent area 410. As described above, since the transparent area 410 is formed of a transparent material, the first light L1 may pass through the transparent area 410 and be directed to the reflective electrode 200. Accordingly, the first light L1 may be reflected by the reflective electrode 200 to be directed to the second substrate 190.

The second light L2 may be light directed to the variable area 420. As described above, since the variable area 420 is in the opaque state, the second light L2 may be absorbed or blocked by the variable area 420.

In conclusion, some of the light of the light emitting layer 320 directed to the first substrate 110 may pass through the transparent area 410 and be reflected by the reflective electrode 200 to be directed to the second substrate 190. In addition, some of the light of the light emitting layer 320 directed to the first substrate 110 may be absorbed or blocked by the variable area 420.

Compared to a case of using the variable area 420 in the transparent state, since the amount of light emitted upward of the display device is small, an image having a relatively low luminance may be displayed.

Meanwhile, in addition to the light generated by the light emitting device 300, when external light is introduced, external light may be reflected by the reflective electrode 200. Accordingly, reflectance by external light may increase, and visibility of the display device may be reduced. However, in FIG. 6, since the variable area 420 is used in the opaque state, only the reflective electrode 200 in an area overlapping the transparent area 410 may be used. That is, compared with the case of using the variable area 420 in the transparent state, the aperture ratio of the display device may be reduced, and an area of the reflective electrode 200 actually used may be reduced. Accordingly, reflectance by external light may be reduced. In particular, in a high luminance environment such as outdoors, the user’s visibility may be improved.

In conclusion, the display device may be selectively driven to be suitable for a low- luminance and high-luminance environment. Specifically, in a case of the low-luminance environment, by driving the variable area 420 in the transparent state, it is possible to implement a high-brightness image while improving the lifespan of the light emitting device 300. Furthermore, in a case of the high-luminance environment, by driving the variable area 420 in the opaque state, reflectance due to external light may be reduced.

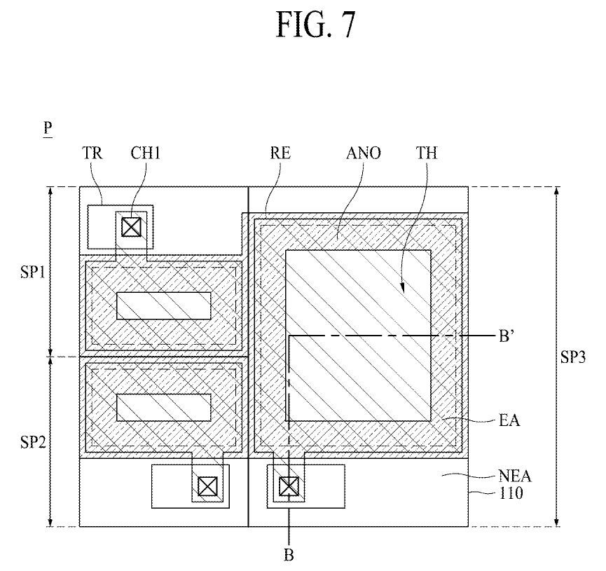

FIG. 7 is a plan view of one pixel according to a second embodiment of the present disclosure.

Compared with FIG. 3, except for a structure of the reflective electrode RE, FIG. 7 illustrates substantially the same structure as FIG. 3. Accordingly, the same reference numerals are used for the same components as the display device illustrated in FIG. 3, and repeated descriptions thereof are omitted.

Referring to FIG. 7, a reflective electrode RE may be disposed under the first electrode ANO. In each of the first sub-pixel SP1, the second sub-pixel SP2, and the third sub-pixel SP3, the reflective electrode RE may be disposed in the entire emission area EA, and may also be disposed in a partial area of the non-emission area NEA. In addition, the reflective electrode RE of each of the first sub-pixel SP1, the second sub-pixel SP2, and the third sub-pixel SP3 may be continuously formed.

In this case, a through hole TH may be disposed in a reflective electrode RE of each of the first sub-pixel SP1, the second sub-pixel SP2, and the third sub-pixel SP3. The disposed through hole TH overlaps the emission area EA, and may be disposed in a central area of the reflective electrode RE. In addition, the first electrode ANO may cover the through hole TH.

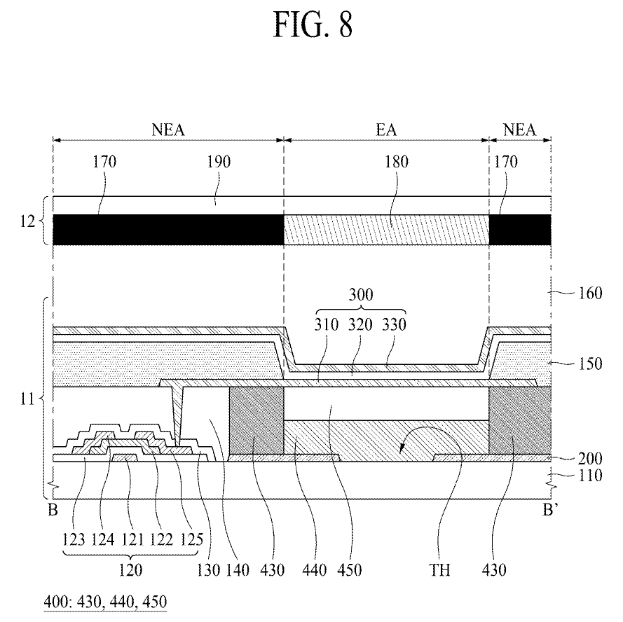

FIG. 8 is a cross-sectional view of one sub-pixel according to a second embodiment of the present disclosure. In detail, it is a cross-sectional view of one sub-pixel taken along line B-B′ illustrated in FIG. 7. FIG. 8 is a cross-sectional view of the thirdsub-pixel SP3, but the present disclosure is not limited thereto. For example, it may be a cross-sectional view of any one of the first sub-pixel SP1 and the second sub-pixel SP2 illustrated in FIG. 7.

In addition, compared with FIG. 4, except for a structure of the reflective electrode RE and the light control layer 400, FIG. 8 illustrates substantially the same structure as FIG. 4. Accordingly, the same reference numerals are used for the same components as the display device illustrated in FIG. 4, and repeated descriptions thereof are omitted.

Referring to FIG. 8, the reflective electrode 200 may be disposed on the first substrate 110. The reflective electrode 200 may be disposed on the same layer as the gate electrode 121, but is not limited thereto. In addition, the reflective electrode 200 may be formed of the same material as the gate electrode 121, but is not limited thereto. For example, the reflective electrode 200 may be disposed on the same layer as the source electrode 124 or the drain electrode 125.

The reflective electrode 200 may include a through hole TH. The through hole TH may penetrate the reflective electrode 200 and expose the first substrate 110. In addition, the through hole TH may be disposed in the emission area EA.

The light control layer 400 may be disposed between the reflective electrode 200 and the light emitting device 300. The light control layer 400 may be disposed in the entire emission area EA and may also be disposed in a partial area of the non-emission area NEA. One side of the light control layer 400 may be in contact with the planarization layer 140. In addition, an upper surface of the light control layer 400 may be in contact with the first electrode 310, and a lower surface of the light control layer 400 may be in contact with the reflective electrode 200. In addition, since the light control layer 400 fills the through hole TH, a portion of the lower surface of the light control layer 400 may also be in contact with the first substrate 110.

The light control layer 400 may include a blocking area 430, a first solvent area 440, and a second solvent area 450.

The first solvent area 440 may be a central area of the light control layer 400. The first solvent area 440 may be disposed in the emission area EA and may not be disposed in the non-emission area NEA. That is, the first solvent area 440 may not overlap the bank 150. In addition, the first solvent area 440 may be in contact with the reflective electrode 200.

The first solvent area 440 may include a material that has a light blocking function and adjusts a light blocking area according to an electric field. In addition, the first solvent area 440 has electrowetting characteristics, and a contact angle with respect to the reflective electrode 200 may vary according to an electric field. That is, an area in which the first solvent area 440 is disposed may vary according to whether a voltage is applied to the reflective electrode 200.Accordingly, the light transmittance of the light control layer 400 may vary.

For example, the first solvent area 440 may include black oil. Alternatively, the first solvent area 440 may include a solvent having a unique color or may include a solvent containing particles such as carbon (C) or titanium oxide (TiO₂) capable of blocking light.

The second solvent area 450 may be a central area of the light control layer 400. The second solvent area 450 may be disposed in the emission area EA and may not be disposed in the non-emission area NEA. That is, the second solvent area 450 may not overlap the bank 150.

The second solvent area 450 may be formed of a solvent having properties that are not mixed with the first solvent area 440. For example, when the first solvent area 440 includes a hydrophobic solvent, the second solvent area 450 may include a hydrophilic solvent. Alternatively, when the first solvent area 440 includes a polar solvent, the second solvent area 450 may include a non-polar solvent. The first solvent area 440 and the second solvent area 450 may fill a space between the reflective electrode 200 and the first electrode 310 and maintain a space between the reflective electrode 200 and the first electrode 310. In addition, the second solvent area 450 may further include a material having a light reflection function.

The blocking area 430 may surround the first solvent area 440 and the second solvent area 450. That is, the first solvent area 440 and the second solvent area 450 may be disposed in a space surrounded by the blocking area 430. One side of the blocking area 430 may be in contact with the planarization layer 140, and the other side of the blocking area 430may be in contact with the first solvent area 440 or the second solvent area 450. In addition, the blocking area 430 may be disposed in the non-emission area NEA and may not be disposed in the emission area EA. That is, the blocking area 430 may overlap the bank 150.

The blocking area 430 may include an organic insulating material such as an acryl resin, an epoxy resin, a phenolic resin, a polyamide resin, a polyimide resin and the like. Alternatively, the blocking area 430 may include an inorganic insulating material such as silicon oxide (SiOx), silicon nitride (SiNx), silicon oxynitride (SiOxNy), and the like. In addition, the blocking area 430 may further include a material that absorbs light. Accordingly, the blocking area 430 may absorb light introduced into the non-emission area NEA.

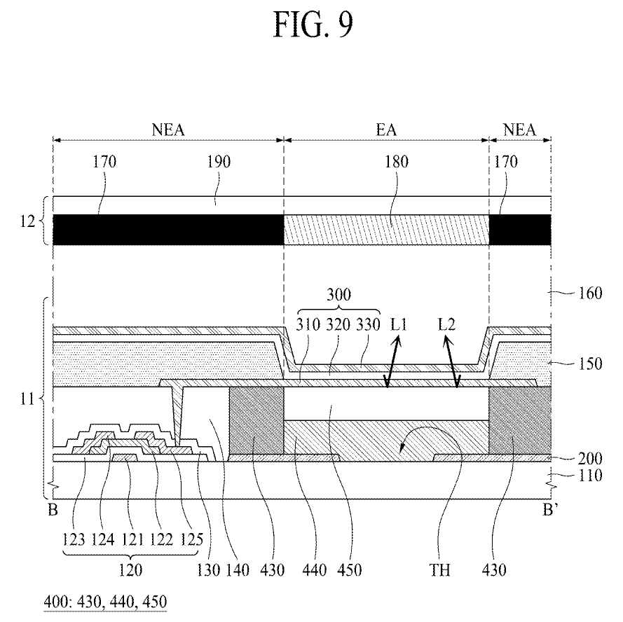

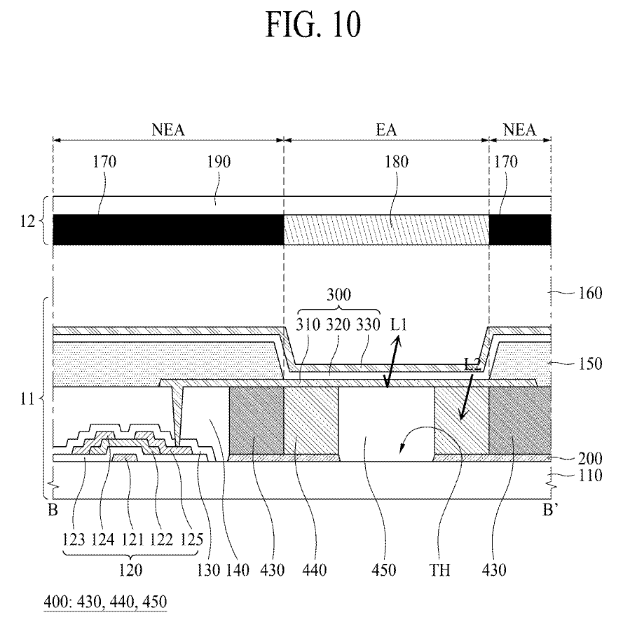

FIGS. 9 and 10 are cross-sectional views of one sub-pixel according to a second embodiment of the present disclosure. In particular, FIGS. 9 and 10 illustrate states of the first solvent area 440 and the second solvent area 450 in detail.

FIG. 9 illustrates a case in which a voltage is not applied to the reflective electrode 200.

Referring to FIG. 9, the first solvent area 440 may be disposed on the reflective electrode 200. The first solvent area 440 may fill the through hole TH and may be in contact with the reflective electrode 200. In addition, the first solvent area 440 may be disposed in the entire emission area EA.

The second solvent area 450 may be disposed on the first solvent area 440. The second solvent area 450 may cover the entire upper surface of the first solvent area 440. In addition, the second solvent area 450 may contact the first electrode 310 and may not contact the reflective electrode 200. In addition, the second solvent area 450 may be disposed in the entire emission area EA.

Meanwhile, some of light generated in the light emitting layer 320 may not be directed to the second substrate 190 but may be directed to the first substrate 110. Referring to FIG. 9, a first light L1 and a second light L2 may be generated in the light emitting layer 320.

The first light L1 may be light generated relatively from a center of the emission area EA, and the second light L2 may be light generated from the emission area EA adjacent to the non- emission area NEA.

The first light L1 and the second light L2 may be directed to the second solvent aera 450. As described above, since the second solvent area 450 includes a material having a light reflection function, the first light L1 and the second light L2 may be reflected by the second solvent aera 450. Accordingly, the first light L1 and the second light L2 may be reflected toward the second substrate 190.

Accordingly, since an amount of light emitted upward of the display device increases, an image having high luminance may be displayed. Particularly, in a low luminance environment such as indoors, the user’s visibility may be improved.

In addition, the second solvent area 450 disposed in the entire emission area EA defined by the bank 150 may be used. That is, the aperture ratio of the display device may be used to the maximum. In particular, since the aperture ratio of the display device is used to the maximum while improving luminance of the display device, the lifespan of the light emitting device 300 may be improved.

Meanwhile, FIG. 10 illustrates a case in which a voltage is applied to the reflective electrode 200. Since a voltage is applied to the reflective electrode 200, an area including the first solvent area 440 and the second solvent area 450 may change.

Referring to FIG. 10, the first solvent area 440 may be disposed on the reflective electrode 200. The first solvent area 440 may be disposed in an area which is in contact with the reflective electrode 200. That is, the first solvent area 440 may expose the through hole TH. In addition, an upper surface of the first solvent area 440 may be in contact with the first electrode 310. In addition, the first solvent area 440 may be disposed in a partial area of the emission area EA adjacent to the non- emission area NEA.

The second solvent area 450 may be disposed on the first substrate 110. A side surface of the second solvent area 450 may be in contact with the first solvent area 440. That is, the first solvent area 440 may surround the second solvent area 450. The second solvent area 450 may fill an inside of the through hole TH. In addition, an upper surface of the second solvent area 450 may be in contact with the first electrode 310. In addition, the second solvent area 450 may be disposed in a partial area of the emission area EA. That is, the second solvent area 450 may be disposed in the remaining area of the emission area EA where the first solvent area 440 is not disposed. In addition, heights of the first solvent area 440 and the second solvent area 450 may be the same.

As described above, some of the light generated in the light emitting layer 320 may not be directed to the second substrate 190, but may be directed to the first substrate 110. Referring to FIG. 10, a first light L1 and a second light L2 may be generated in the light emitting layer 320.

The first light L1 may be light generated relatively from the center of the emission area EA, and the second light L2 may be light generated from the emission area EA adjacent to the non- emission area NEA.

The first light L1 may be directed to the second solvent area 450. As described above, since the second solvent area 450 includes a material having a light reflection function, the first light L1 may be reflected by the second solvent area 450. Accordingly, the first light L1 and the second light L2 may be reflected toward the second substrate 190.

The second light L2 may be directed to the first solvent area 440. As described above, since the first solvent area 440 includes a material having a light blocking function, the second light L2 may be absorbed or blocked by the first solvent area 440.

In conclusion, some of the light of the light emitting layer 320 directed to the first substrate 110 may be reflected by the second solvent area 450 and may be directed to the second substrate 190. In addition, some of the light of the light emitting layer 320 directed to the first substrate 110 may be absorbed or blocked by the first solvent area 440.

Compared to a structure in which the second solvent aera 450 covers the entire upper surface of the first solvent area 440, since the amount of light emitted upward of the display device is small, an image having a relatively low luminance may be displayed.

Meanwhile, in addition to the light generated by the light emitting device 300, when external light is introduced, external light may be reflected by the second solvent area 450. Accordingly, reflectance by external light may increase and visibility of the display device may decrease. However, in FIG. 10, light incident through the first solvent area 440 may be absorbed or blocked. That is, compared to a structure in which the second solvent area 450 covers the entire upper surface of the first solvent area 440, the aperture ratio of the display device may be reduced, and an area of the first solvent area 440 that is actually used may be reduced. Accordingly, reflectance by external light may be reduced. In particular, in a high luminance environment such as outdoors, the user’s visibility may be improved.

In conclusion, the display device may be selectively driven to be suitable for a low-luminance and high-luminance environment. Specifically, in a case of the low-luminance environment, by driving the second solvent area 450 in a state in which the first solvent area 440 is covered, it is possible to implement a high-brightness image while improving the lifespan of the light emitting device 300. Furthermore, in a case of the high-luminance environment, by driving the first solvent area 440 in an exposed state. reflectance due to external light may be reduced.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate having a plurality of sub-pixels, each of the plurality of sub-pixels including an emission area and a non-emission area adjacent to the emission area,
wherein each of the plurality of sub-pixels include:
a reflective electrode disposed on the substrate in the emission area;
a light control layer disposed on the reflective electrode, the light control layer including a variable area; and
a light emitting device disposed on the light control layer, the light emitting device including a first electrode,
wherein the variable area is disposed in the emission area adjacent to the non-emission area, and
wherein a light transmittance of the variable area is changed, according to whether voltages are applied to the first electrode and the reflective electrode.

2. The display device of claim 1, wherein the light control layer further includes a transparent area disposed in the emission area and a blocking area disposed in the non-emission area, and
wherein the variable area is disposed between the transparent area and the blocking area.

3. The display device of claim 2, wherein the variable area surrounds the transparent area, and the blocking area surrounds the variable area.

4. The display device of claim 2, wherein the reflective electrode is disposed under the variable area and the transparent area.

5. The display device of claim 1, wherein the variable area is in contact with the first electrode and the reflective electrode.

6. The display device of claim 1, wherein when voltages area not applied to the first electrode and the reflective electrode, the variable area is in a transparent state, and
wherein when voltages are applied to the first electrode and the reflective electrode, the variable area is in an opaque state.

7. The display device of claim 1, wherein when voltages are not applied to the first electrode and the reflective electrode, the variable area transmits light, and
wherein when voltages are applied to the first electrode and the reflective electrode, the variable area blocks or absorbs light.

8. The display device of claim 1, wherein the plurality of sub-pixels include a first sub-pixel and a second sub-pixel adjacent to each other, and
wherein the reflective electrode disposed in the first sub-pixel and the reflective electrode disposed in the second sub-pixel have a same potential.

9. The display device of claim 8, wherein the reflective electrode disposed in the first sub-pixel and the reflective electrode disposed in the second sub-pixel are continuously formed.

10. The display device of claim 1, wherein the first electrode and the reflective electrode are not electrically connected to each other and receive different voltages from each other.

11. A display device comprising:
a substrate having a plurality of sub-pixels, each of the plurality of sub-pixels including an emission area and a non-emission area adjacent to the emission area,
wherein each of the plurality of sub-pixels include:
a reflective electrode disposed on the substrate in the emission area;
a light control layer disposed on the reflective electrode, the light control layer including a first solvent area; and
a light emitting device disposed on the light control layer, the light emitting device including a first electrode,
wherein the first solvent area is disposed in the emission area and includes a material having a light blocking function, and
wherein an area in which the first solvent area is disposed changes according to whether a voltage is applied to the reflective electrode.

12. The display device of claim 11, wherein the light control layer further includes a second solvent area disposed in the emission area and a blocking area disposed in the non-emission area, and
wherein the blocking area surrounds the first solvent area and the second solvent area.

13. The display device of claim 12, wherein the reflective electrode is disposed under the first solvent area and a through hole is disposed in a central area of the reflective electrode.

14. The display device of claim 13, wherein when a voltage is not applied to the reflective electrode, a solvent of the first solvent area extends into the through hole and contacts the reflective electrode, and
wherein when a voltage is not applied to the reflective electrode, the second solvent area is disposed on the first solvent area.

15. The display device of claim 14, wherein when a voltage is not applied to the reflective electrode, the first solvent area and the second solvent area are disposed in the entire emission area.

16. The display device of claim 13, wherein when a voltage is applied to the reflective electrode, the first solvent area exposes the through hole and is in contact with the reflective electrode, and
wherein when a voltage is applied to the reflective electrode, a solvent of the second solvent area extends into an inside of the through hole.

17. The display device of claim 16, wherein when a voltage is applied to the reflective electrode, the first solvent area surrounds the second solvent area.

18. The display device of claim 16, wherein when a voltage is applied to the reflective electrode, the first solvent area is disposed in a partial area of the emission area adjacent to the non-emission area, and
wherein when a voltage is applied to the reflective electrode, the second solvent area is disposed in a remaining area of the emission area where the first solvent area is not disposed.

19. The display device of claim 12, wherein the second solvent area includes a material having a light reflection function.
